(19) United States
(12) Patent Application Publication
(10) Pub. No.: US 2012/0244717 A1
(43) Pub. Date: Sep. 27, 2012

(54) RESIN REMOVAL METHOD, RESIN REMOVAL APPARATUS, AND METHOD OF MANUFACTURING SEMICONDUCTOR DEVICE

(76) Inventors: Yingkang ZHANG, Kanagawa (JP); Katsuyoshi KODERA, Kanagawa (JP); Tetsuaki MATSUNAWA, Kanagawa (JP); Masanori TAKAHASHI, Kanagawa (JP)

(21) Appl. No.: 13/233,583

(22) Filed: Sep. 15, 2011

(30) Foreign Application Priority Data
Mar. 23, 2011 (JP) 2011-064671

(51) Int. Cl. H01L 21/268; B29C 35/08

(52) U.S. Cl. 438/709; 264/405; 425/174.4; 257/E21.347

(57) ABSTRACT

According to one embodiment, a resin removal method is provided. In the resin removal method, near-field light is generated in a local area of a pattern concave-convex portion on a pattern master used for imprinting by irradiating the pattern master with ultraviolet light in an ashing gas atmosphere which removes resin attached to the pattern master. Then, the resin is removed from the pattern master by using the ashing gas and the near-field light.

### CROSS-REFERENCE TO RELATED APPLICATIONS

This application is based upon and claims the benefit of priority from the prior Japanese Patent Application No. 2011-064671, filed on Mar. 23, 2011; the entire contents of which are incorporated herein by reference.

### FIELD

Embodiments described herein relate generally to a resin removal method, a resin removal apparatus, and a method of manufacturing semiconductor device.

### BACKGROUND

Imprint lithography is a technique for transferring a transfer pattern onto a substrate at the same size by causing a fine three-dimensional pattern (mold pattern) formed in a mold, which is a mold of the transfer pattern, to come into contact with an imprint material (resin) on the substrate. If the mold has defects, the defects are included in the transfer pattern, so the mold needs to be defect-free.

When the imprint process is performed, a resin is dropped onto the substrate as an imprint material, and thereafter, the mold is pressed onto the resin on the substrate. Further, the resin is cured in this state, and thereby a transfer pattern corresponding to the mold pattern is patterned into the resin on the substrate. Then, the mold is peeled off from the resin, and the transfer process to the resin is completed.

However, when the mold is peeled off from the cured resin, residue of the resin may be attached to the pattern surface of the mold. Therefore, if the residue of the resin is attached to the pattern surface of the mold, the resin is desired to be quickly and efficiently removed from the pattern surface of the mold without damaging the mold.

### BRIEF DESCRIPTION OF THE DRAWINGS

FIG. 1 is a diagram illustrating a configuration of a resin removal apparatus according to a first embodiment;

FIG. 2 is a diagram for explaining a resin removal method according to the first embodiment;

FIG. 3 is a diagram illustrating a correspondence relationship between a mold pattern pitch and an irradiation wavelength;

FIG. 4 is a diagram for explaining a method of forming linearly polarized light according to a second embodiment;

FIGS. 5A to 5C are diagrams for explaining a polarization direction of TM polarized light; and

FIGS. 6A to 6C are diagrams illustrating energy distribution of near-field light formed in a local area when polarized light is irradiated to a concave-convex pattern.

### DETAILED DESCRIPTION

According to one embodiment, a resin removal method is provided. In the resin removal method, near-field light is generated in a local area of a pattern concave-convex portion on a pattern master used for imprinting by irradiating the pattern master with ultraviolet light in an ashing gas atmosphere which removes resin attached to the pattern master. Then, the resin is removed from the pattern master by using the ashing gas and the near-field light.

Exemplary embodiments of the resin removal method and the resin removal apparatus will be explained below in detail with reference to the accompanying drawings. The present invention is not limited to the embodiments.

### First Embodiment

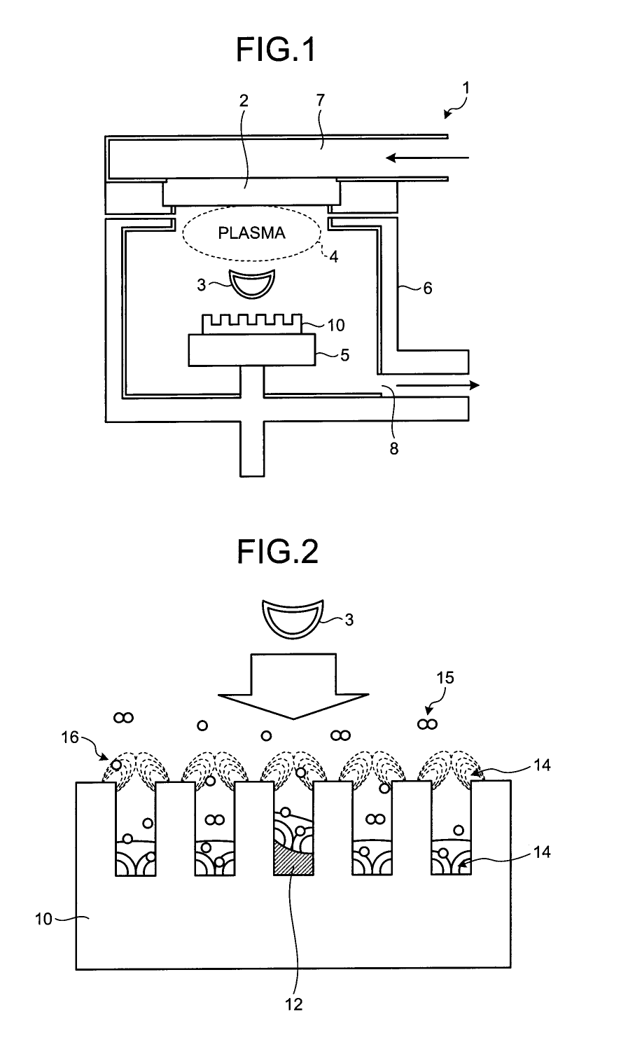

FIG. 1 is a diagram illustrating a configuration of a resin removal apparatus according to a first embodiment. FIG. 1 illustrates a cross-sectional configuration of a resin removal apparatus (cleaning apparatus) 1 for cleaning a mold 10. The resin removal apparatus 1 is an apparatus for removing resin residue (resin residue 12 described below) attached to the mold 10 by ashing. The resin removal apparatus 1 according to the present embodiment generates near-field light in a local area of a fine pattern concave-convex portion formed on the mold 10 by irradiating the mold 10 with ultraviolet light. The resin removal apparatus 1 breaks chemical bond of the resin by using the near-field light.

The mold 10 is a pattern master (template) (mold to be cleaned) for imprint lithography, and a concave-convex pattern is formed on an upper surface (pattern surface) of the mold 10 as a mold pattern. The resin residue 12 is a residue of resin (organic matter or the like) attached to a pattern concave portion or the like on the mold 10.

The resin removal apparatus 1 includes a discharge unit 2, an ultraviolet light source 3, a mold stage 5, a cleaning chamber 6, an ashing gas introduction pipe 7, and an exhaust pipe 8. The discharge unit 2 generates a plasma 4 in an area between the discharge unit 2 and the mold 10. Thereby, a part of the ashing gas is converted into plasma, and ionized oxygen radicals and the like are introduced near the mold 10.

The ultraviolet light source 3 of the present embodiment is a light source for irradiating the mold 10 with ultraviolet light. The ultraviolet light source 3 is, for example, an excimer lamp that is a gas discharge lamp in which gas including at least one of elements F, Ar, Kr, and Xe is enclosed as discharge gas. For example, an excimer lamp that uses argon fluoride (ArF) gas as discharge gas generates ultraviolet light (excimer light) with a center wavelength (peak) of 193 nm. The ultraviolet light source 3 is mounted so that the pattern surface on the mold 10 is irradiated with the ultraviolet light. For example, the ultraviolet light source 3 is mounted in front of (immediately above) the pattern surface.

When the mold 10 to be cleaned is a quartz mold, the ultraviolet light emitted from the ultraviolet light source 3 may be irradiated to the mold 10 from the back surface side of the pattern surface, because the ultraviolet light can pass through quartz. In this case, the mold stage 5 and a heater described below are formed of a substantially transparent material.

The mold stage 5 is a pedestal on which the mold 10 is mounted and fixed. The mold stage 5 has a heater (not illustrated in the drawings) for heating the plasma 4 inside thereof.

The cleaning chamber 6 has a substantially cylindrical shape with a bottom and surrounds side surfaces and bottom surface of a vacuum reaction chamber in which the ashing process is performed. The discharge unit 2 is disposed above the cleaning chamber 6 and the ashing gas introduction pipe 7 having a pipe shape, which is a unit for introducing ashing gas, is provided above the discharge unit 2. The exhaust pipe 8 having a pipe shape, which is a unit for exhausting gas, is provided below the cleaning chamber 6.

The ashing gas introduction pipe 7 is connected with a gas supply source (not illustrated in the drawings) via a pipe for supplying gas. Examples of the ashing gas supplied from the gas supply source include oxygen gas.

When removing the resin residue 12 on the mold 10, the mold 10 is brought into the resin removal apparatus 1 and fixed on the mold stage 5. Thereafter, the ashing gas is introduced into the cleaning chamber 6 from the ashing gas introduction pipe 7. In the cleaning chamber 6, the plasma 4 is generated by the discharge unit 2. At this time, the plasma 4 is heated by radiation heat from the heater included in the mold stage 5. In this way, the ashing of the mold 10 is performed.

FIG. 2 is a diagram for explaining the resin removal method according to the first embodiment. FIG. 2 illustrates a schematic cross-sectional view of the mold 10 when the mold 10 is cleaned. The ashing of the resin removal apparatus 1 is performed by reacting oxygen with resin which is an organic compound. The reaction mechanism at this time includes (1) transporting reactive species (oxygen radicals or the like) to the surface of the resin, (2) absorption of the reactive species, (3) reaction on the surface of the resin, (4) detachment of reaction product, (5) removal of the reaction product by volatilization, and the like.

The composition of the ashing gas used by the resin removal apparatus 1 is mainly oxygen molecules (O₂) 15. To increase decomposition efficiency of the resin residue 12, a small amount of halogen series gas (not illustrated in the drawings) may be added to the ashing gas consisting mainly of oxygen molecules 15. A part of the ashing gas is converted into plasma by electric discharge or the like and introduced near the mold 10. Thereby, an ashing gas atmosphere is formed around the mold 10. Specifically, the oxygen molecules 15 and the ionized oxygen radicals (0*) 16 generated by the oxygen molecules 15 converted into plasma are introduced around the mold 10.

When the ultraviolet light source 3 irradiates the mold 10 with ultraviolet light, near-field light 14 is generated in a local area of a fine pattern concave-convex portion on the mold 10. The near-field light 14 is non-propagating light (electromagnetic field) independent of wavelength, which is generated around a microscopic object in an area several times the curvature radius of the microscopic object when propagating light is irradiated to the microscopic object (local area) having a curvature radius of several nm. Although the near-field light 14 has a very strong electromagnetic component, the near-field light 14 has characteristics that the electromagnetic component rapidly decreases as the near-field light 14 goes away from the surface of the object. The portions of the microscopic objects in the mold 10 are a top end portion of the pattern convex portion, a bottom portion of the pattern concave portion, and the like.

When the curvature radius of the microscopic object is a, and the distance from the microscopic object is r, the intensity I of the near-field light is represented by the following formula (I).

I=exp(−r/a)/r (1)

In the fine pattern on the mold 10, an area whose curvature radius is particularly small is a corner of a pattern concave portion. Specifically, the finer the pattern on the mold 10 is, the smaller the curvature radius of the pattern concave portion is, and the stronger the intensity of the near-field light 14 generated near the pattern concave-convex portion is.

When the near-field light 14 is generated in a local area of the fine pattern concave-convex portion formed on the mold 10, the phenomenon as described below occurs. First, the energy distribution of the electromagnetic field is strengthened in the pattern concave portion by the effect of the near-field light 14. The oxygen molecules 15 that enter the pattern concave portion are excited and become the oxygen radicals 16, and the density of the oxygen radicals 16 increases in the local area. When the oxygen radicals 16 react with the resin residue 12 attached inside the pattern concave portion, volatile reaction products CO₂ and H₂O are generated. In other words, when a part of the resin residue 12, in which the chemical bond is broken by the oxygen radicals 16, combine with the oxygen radicals 16, volatile matter, which is an oxidized resin residue 12, is generated. The CO₂ and the H₂O evaporate, and thereby, the oxidized resin residue 12 evaporates.

Second, the near-field light 14 directly affects the attached resin residue 12, and the effect for breaking the chemical bond of the resin is accelerated. Thereby, the near-field light 14 decreases adhesion force between the mold 10 and the resin residue 12 and decomposes a part of the resin residue 12 into carbon and hydrogen. Thereby, the chemical bonding of the attached resin residue 12 is broken and the process for decomposing the attached resin residue 12 is accelerated. Therefore, the resin residue 12 is quickly and sufficiently removed from the mold 10.

The mold 10 from which the resin residue 12 is removed by the resin removal apparatus 1 is used for imprinting to a substrate such as a wafer. For example, the imprinting to a wafer is performed on each of predetermined layers of wafer process. At this time, in each layer, the imprinting to the wafer is performed by using the mold 10 from which the resin residue 12 is removed, and thereby a semiconductor device (semiconductor integrated circuit) is manufactured.

Specifically, when the imprint process is performed, a resin is dropped onto the wafer as an imprint material, and thereafter, the mold 10 is pressed onto the resin on the wafer. Further, the resin is cured in this state, and thereby a transfer pattern corresponding to the mold pattern is patterned into the resin on the wafer. Then, the mold is peeled off from the resin, and the transfer process to the resin is completed.

When the imprint process is performed, if the resin residue 12 is attached inside the pattern concave portion of the mold 10, the resin residue 12 is removed by the resin removal apparatus 1, and then the imprint process is restarted. Whether to remove the resin residue 12 by the resin removal apparatus 1 may be determined each time a predetermine number of imprint operations have been performed, or each time the imprint operation has been performed on a predetermined number of wafers.

After the transfer pattern corresponding to the mold pattern is patterned into the resin, the lower side of the wafer is etched by using the pattern formed in the resin (resist pattern) as a mask. Thereby, an actual pattern corresponding to the mold pattern is formed on the wafer. When manufacturing a semiconductor device, a film formation process on the wafer, the imprint process described above, an etching process, and the like are repeatedly performed for each layer. The resin residue 12 on the mold 10 is removed as needed.

When the energy density of the ultraviolet light irradiated to the mold 10 is increased, the removal effect of the resin residue 12 can be enhanced, and thereby it is possible to reduce the time taken to remove the resin residue 12 in the pattern concave portion. Therefore, the energy density of the ultraviolet light irradiated to the mold 10 is set to, for example, 10 J/cm².

A separating material may be coated on the pattern surface (mold surface) of the mold 10 so that the resin is not attached to the mold 10 when the mold is peeled off from the cured imprint material (resin).

The entire mold 10 may be irradiated with the ultraviolet light by the ultraviolet light source 3, or a predetermined area where the resin residue 12 is attached (a part of the mold 10) may be irradiated with the ultraviolet light.

In the first embodiment and a second embodiment described below, the wavelength of the ultraviolet light irradiated to the mold 10 may be changed according to a mold pattern pitch of the mold 10 and the curvature of the mold pattern. This is because the optimal wavelength of the ultraviolet light to be irradiated depends on the mold pattern pitch.

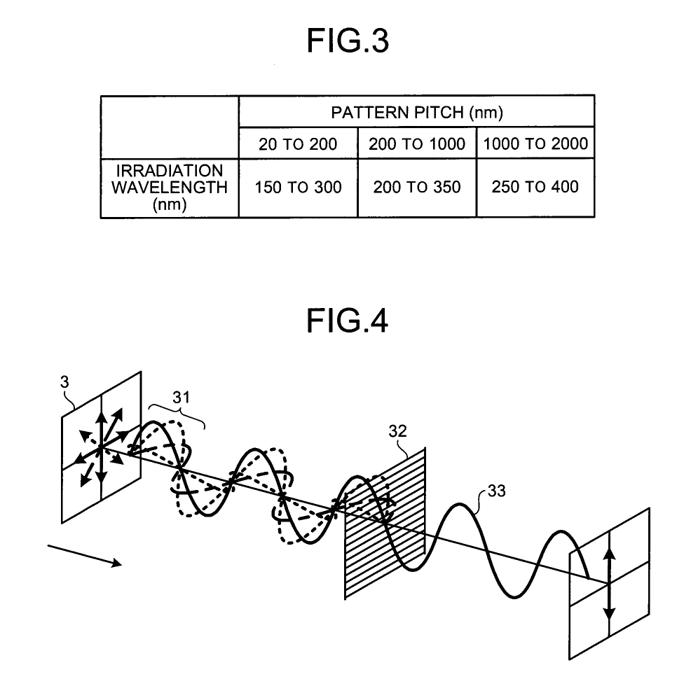

FIG. 3 is a diagram illustrating a correspondence relationship between the mold pattern pitch and an irradiation wavelength. The correspondence relationship between the pattern pitch of the mold 10 and the irradiation wavelength illustrated in FIG. 3 is an example. As illustrated in FIG. 3, when the pattern pitch of the mold 10 is 20 nm to 200 nm, the resin removal apparatus 1 sets the wavelength (irradiation wavelength) of the ultraviolet light to be irradiated to the mold 10 to 150 nm to 300 nm.

When the pattern pitch of the mold 10 is 200 nm to 1000 nm, the resin removal apparatus 1 sets the irradiation wavelength to 200 nm to 350 nm. When the pattern pitch of the mold 10 is 1000 nm to 2000 nm, the resin removal apparatus 1 sets the irradiation wavelength to 250 nm to 400 nm.

In this way, the mold 10 is irradiated with the ultraviolet light having an irradiation wavelength according to the mold pattern pitch, so that it is possible to generate near-field light 14 having an energy intensity according to the mold pattern pitch. Therefore, the resin residue attached inside the fine pattern concave portion can be efficiently removed.

For example, the ultraviolet light irradiated to the mold 10 is assumed to be ultraviolet light having a plurality of wavelengths (broadband irradiation light). Thereby, even when a plurality of types of pattern pitches are included in the mold 10, ultraviolet light having wavelengths according to the pattern pitches can be irradiated. The ultraviolet light irradiated to the mold 10 may be ultraviolet light having a single wavelength.

As described above, according to the first embodiment, the mold 10 is irradiated by using the ultraviolet light source 3 in the ashing gas atmosphere, so that it is possible to generate the near-field light 14 in a local area of the fine pattern concave-convex portion. By the effect of the near-field light 14, breaking and decomposition of chemical bond of the attached resin residue 12 and oxidization and volatilization of the resin residue 12 caused by the reaction of the oxygen radicals 16 generated by the near-field light 14 progress in parallel. Therefore, the resin residue attached inside the fine pattern concave portion can be quickly and efficiently removed.

The resin residue 12 is removed by using the oxygen radicals 16, so that it is possible to remove the resin residue 12 from the mold 10 without damaging the mold 10 even when the resin residue 12 is attached to the fine pattern.

### Second Embodiment

Next, a second embodiment will be described with reference to FIGS. 4 to 6. In the second embodiment, TM polarized light is used as the ultraviolet light irradiated to the mold 10.

FIG. 4 is a diagram for explaining a method of forming linearly polarized light according to the second embodiment. The oscillation directions of electric field of the ultraviolet light generated from the ultraviolet light source 3 are random, and the light in this state is unpolarized light 31. When the unpolarized light 31 passes through a predetermined optical element (for example, polarization filter) (polarization forming element 32), light (linearly polarized light 33) in which electric field oscillation directions are uniform can be obtained.

By this method, the electric field oscillation directions of incident light to the mold 10 can be uniform. When the ultraviolet light of the linearly polarized light 33 is irradiated to the mold 10, if the electric field oscillation direction of the ultraviolet light is perpendicular to the longitudinal direction of main pattern on the mold 10, the polarization direction of the ultraviolet light is defined as the TM polarized light. On the other hand, if the electric field oscillation direction of the incident ultraviolet light is in parallel with the longitudinal direction of main pattern on the mold 10, the polarization direction of the ultraviolet light is defined as TE polarized light. Here, the main pattern is a fine pattern in which the resin residue 12 occurs easily, a pattern which is most often formed among the patterns formed on the mold 10 (for example, memory cell pattern), or the like.

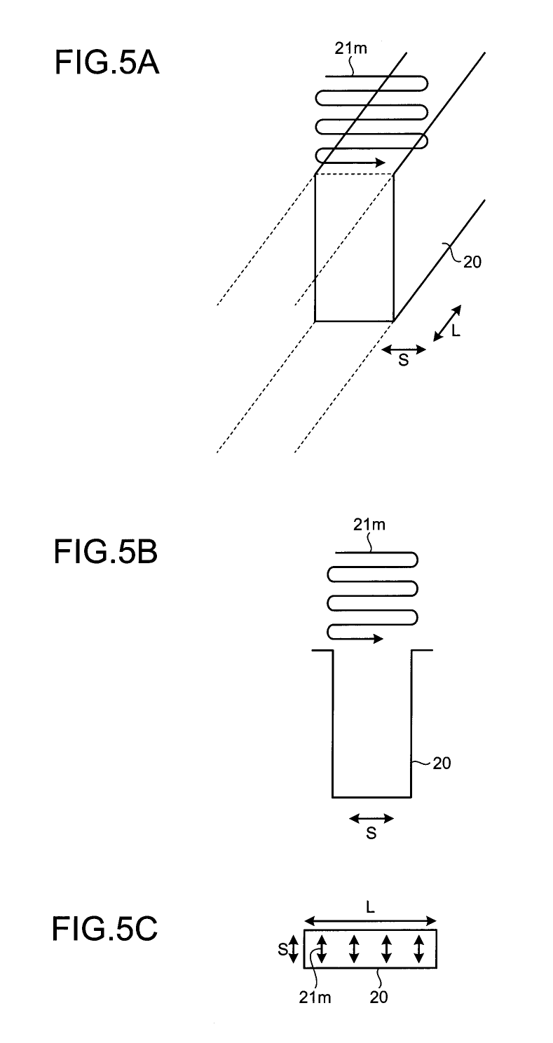

FIGS. 5A to 5C are diagrams for explaining a polarization direction of the TM polarized light. FIGS. 5A to 5C illustrate the polarization direction of TM polarized light 21m with respect to a concave-convex pattern 20, which is an example of the main pattern on the mold 10.

FIG. 5A illustrates a perspective view of the concave-convex pattern 20. FIG. 5B illustrates a cross-sectional view obtained by cutting off the concave-convex pattern 20 in a direction perpendicular to a longitudinal direction L. FIG. 5C illustrates a top view of the concave-convex pattern 20.

As illustrated in FIGS. 5A to 5C, the electric field oscillation direction of the TM polarized light 21m is perpendicular to the longitudinal direction L of the concave-convex pattern 20. In other words, the electric field oscillation direction of the TM polarized light 21m is in parallel with a transverse direction S of the concave-convex pattern 20.

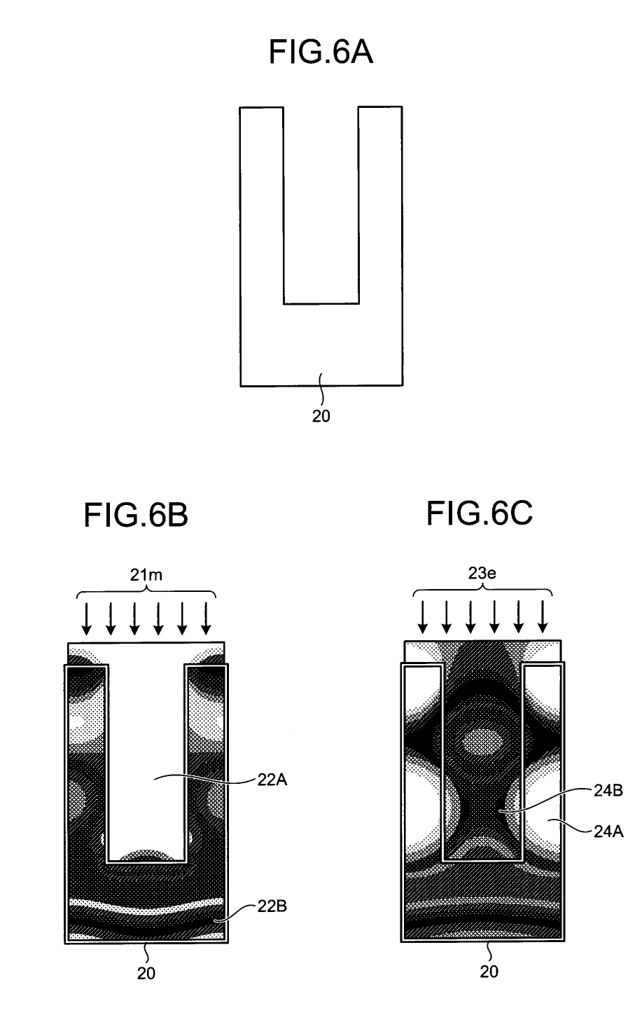

FIGS. 6A to 6C are diagrams illustrating energy distribution of near-field light formed in a local area when polarized light is irradiated to the concave-convex pattern. FIG. 6A illustrates a cross-sectional view of the concave-convex pattern 20 formed on the mold 10. FIG. 6B illustrates energy distribution of the near-field light 14 formed in a local area near the concave-convex pattern 20 when the TM polarized light 21m is irradiated to the concave-convex pattern 20. FIG. 6C illustrates energy distribution of the near-field light 14 formed in a local area near the concave-convex pattern 20 when the TE polarized light 23e is irradiated to the concave-convex pattern 20.

Among the hatched areas illustrated in FIGS. 6B and 6C, areas of light color indicate areas of high energy, and areas of dark color indicate areas of low energy. For example, an area 22A illustrated in FIG. 6B is an area of the highest energy, and an area 22B is an area of the lowest energy. An area 24A illustrated in FIG. 6C is an area of the highest energy, and an area 24B is an area of the lowest energy.

In the case of FIG. 6B, it is known that the energy is high inside the pattern concave portion. Therefore, when the TM polarized light 21m is irradiated to the concave-convex pattern 20, the near-field light energy largely affects the resin residue 12. Thereby, breaking and decomposition of chemical bond of the resin residue 12 attached inside the pattern concave portion and oxidization and volatilization of the resin residue 12 caused by the reaction of the oxygen radicals 16 generated by the near-field light energy with the resin residue 12 progress in parallel. Therefore, the resin residue 12 attached inside the fine pattern concave portion can be efficiently removed.

In the case of FIG. 6C, it is known that the energy is low inside the pattern concave portion. Therefore, when the TE polarized light 23e is irradiated to the concave-convex pattern 20, breaking and decomposition effects of chemical bond of the resin residue 12 attached inside the pattern concave portion and formation effect of the oxygen radicals 16 are low, so that the resin residue 12 attached inside the fine pattern concave portion cannot be efficiently removed.

Therefore, the resin removal apparatus 1 of the present embodiment irradiates the main pattern on the mold 10 with the ultraviolet light of the TM polarized light by using the ultraviolet light source 3 and the polarization forming element 32 in the ashing gas atmosphere. Thereby, it is possible to efficiently generate the near-field light 14 in a local area of the fine pattern concave-convex portion.

As described above, according to the second embodiment, the main pattern on the mold 10 is irradiated with the ultraviolet light of the TM polarized light 21m by using the ultraviolet light source 3 and the polarization forming element 32 in the ashing gas atmosphere, so that it is possible to efficiently generate the near-field light 14 in a local area of the fine pattern concave-convex portion. Therefore, the resin residue 12 attached inside the fine pattern concave-convex portion can be efficiently removed.

As described above, according to the first and second embodiments, it is possible to quickly and efficiently remove the resin residue 12 from the pattern surface of the mold without damaging the mold 10.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A resin removal method comprising:
generating near-field light in a local area of a pattern concave-convex portion on a pattern master used for imprinting by irradiating the pattern master with ultraviolet light in an ashing gas atmosphere which removes resin attached to the pattern master; and
removing the resin from the pattern master by using the ashing gas and the near-field light.

2. The resin removal method according to claim 1, wherein, when generating the near-field light, a main pattern on the pattern master is irradiated with ultraviolet light of TM polarized light.

3. The resin removal method according to claim 1, wherein a wavelength of the ultraviolet light irradiated to the master pattern corresponds to a pattern pitch of a pattern formed on the pattern master.

4. The resin removal method according to claim 1, wherein a wavelength of the ultraviolet light irradiated to the master pattern is equal to or greater than 150 nm and equal to or smaller than 400 nm.

5. The resin removal method according to claim 1, wherein the ultraviolet light is irradiated from a surface of the pattern master on which a pattern is formed.

6. The resin removal method according to claim 1, wherein the ultraviolet light is irradiated from a back surface opposite to a surface of the pattern master on which a pattern is formed.

7. The resin removal method according to claim 1, wherein the ashing gas includes oxygen plasma ashing gas.

8. A resin removal apparatus comprising an ultraviolet light irradiation unit configured to irradiate a pattern master used for imprinting with ultraviolet light in an ashing gas atmosphere which removes resin attached to the pattern master,
wherein near-field light is generated in a local area of a pattern concave-convex portion on the pattern master by irradiating the ultraviolet light and the resin is removed from the pattern master by using the ashing gas and the near-field light.

9. The resin removal apparatus according to claim 8, wherein, when generating the near-field light, a main pattern on the pattern master is irradiated with ultraviolet light of TM polarized light.

10. The resin removal apparatus according to claim 8, wherein the ultraviolet light irradiation unit irradiates the pattern master with ultraviolet light having a wavelength corresponding to a pattern pitch of a pattern formed on the pattern master.

11. The resin removal apparatus according to claim 8, wherein the ultraviolet light irradiation unit irradiates the pattern master with ultraviolet light having a wavelength equal to or greater than 150 nm and equal to or smaller than 400 nm.

12. The resin removal apparatus according to claim 8, wherein the ultraviolet light irradiation unit irradiates the ultraviolet light from a surface of the pattern master on which a pattern is formed.

13. The resin removal apparatus according to claim 8, wherein the ultraviolet light irradiation unit irradiates the ultraviolet light from a back surface opposite to a surface of the pattern master on which a pattern is formed.

14. The resin removal apparatus according to claim 8, wherein the ashing gas includes oxygen plasma ashing gas.

15. A method of manufacturing a semiconductor device, the method comprising:
generating near-field light in a local area of a pattern concave-convex portion on a pattern master used for imprinting by irradiating the pattern master with ultraviolet light in an ashing gas atmosphere which removes resin attached to the pattern master;
removing the resin from the pattern master by using the ashing gas and the near-field light; and
forming a pattern on a substrate by using the pattern master from which the resin is removed.

16. The method of manufacturing a semiconductor device according to claim 15, wherein, when generating the near-field light, a main pattern on the pattern master is irradiated with ultraviolet light of TM polarized light.

17. The method of manufacturing a semiconductor device according to claim 15, wherein a wavelength of the ultraviolet light irradiated to the master pattern corresponds to a pattern pitch of a pattern formed on the pattern master.

18. The method of manufacturing a semiconductor device according to claim 15, wherein a wavelength of the ultraviolet light irradiated to the master pattern is equal to or greater than 150 nm and equal to or smaller than 400 nm.

19. The method of manufacturing a semiconductor device according to claim 15, wherein the ultraviolet light is irradiated from a surface of the pattern master on which a pattern is formed.

20. The method of manufacturing a semiconductor device according to claim 15, wherein the ultraviolet light is irradiated from a back surface opposite to a surface of the pattern master on which a pattern is formed.
